(19) United States
(12) Patent Application Publication
(10) Pub. No.: US 2005/0112887 A1
(43) Pub. Date: May 26, 2005

(54) Etching process

(76) Inventor: Junichi Muramoto, Tokyo (JP)

Correspondence Address: Bell, Boyd & Lloyd LLC, P.O. Box 1135, Chicago, IL, 60690, US

(21) Appl. No.: 10/977,302

(22) Filed: Oct. 29, 2004

(30) Foreign Application Priority Data
Oct. 29, 2003 (JP) P2003-368221

(51) Int. Cl. H01L 21/4763; H01L 21/302; H01L 21/461

(52) U.S. Cl. 438/689

(57) ABSTRACT

An etching process is provided. The etching process allows etching and removing with a sufficient rate, from a fine etching opening, a sacrificing layer and thereby can form a structure that has a large hollow portion or a complicatedly constituted space portion and furthermore a structure high in the aspect ratio with excellent shape accuracy and without deteriorating a surface state. In the etching process, a work is exposed to a processing fluid that contains an etching reaction species and the processing fluid is maintained in a state where it is flowed relative to the work. In this state, on a surface of the work, illumination light is intermittently illuminated to heat the work intermittently. Thereby, the processing fluid in the neighborhood of the work is intermittently heated and thereby expanded and contracted to etch. As the processing fluid, a substance that contains an etching reaction species and is in a super critical state can be preferably used.

### CROSS REFERENCES TO RELATED APPLICATIONS

This application claims priority to Japanese Patent Application No. P2003-368221 filed on Oct. 29, 2003, the disclosure of which is incorporated by reference herein.

### BACKGROUND OF THE INVENTION

The present invention relates to an etching process. In particular, the present invention relates to an etching process that is applied when in the manufacture of a semiconductor device or a micromachine, a sacrificing layer is selectively etched and removed to form a fine three-dimensional structure.

With the progress of the miniaturization technology, micromachines (Micro Electro Mechanical Systems: MEMS) and small devices in which a micromachine is assembled are gathering attention. A micromachine is an element in which a moving portion that is made of a three-dimensional structure formed on a substrate such as a silicon substrate or a glass substrate and a semiconductor integrated circuit and the like that control the drive of the moving portion are electrically and mechanically combined, and constitutes a resonator element and the like such as an optical element and a FBAR (Film Bulk Acoustic Resonator).

In the field of such micromachines and semiconductors, a process is generally known to carry out in such a manner that a scarifying layer is beforehand formed on a substrate, a structure layer is formed on the sacrificing layer followed by patterning, thereafter the sacrificing layer is selectively etched and removed, and thereby a three-dimensional structure in which below a patterned structure layer a hollow portion is disposed or a three-dimensional structure with a high aspect ratio is formed. As the sacrificing layer, silicon oxide (SiO₂) or silicon (Si) is used, and when the sacrificing layer is etched and removed, an etchant that can speedily and selectively etch the sacrificing layer is used to etch. For instance, in the case of a sacrificing layer due to silicon oxide being formed, a fluorine (F)-containing etching liquid is used to etch, and in the case of a sacrificing layer being formed of silicon an etching gas such as gaseous xenon fluoride (XeF₂) or bromine fluoride (BrF₃) is used to etch.

Furthermore, for instance, in the case of a three-dimensional structure with a hollow portion below a structure layer being formed, firstly, as shown in FIG. 6A, a sacrificing layer 2 is patterned on an upper portion of a substrate 1, and a structure layer 3 is formed so as to cover on the substrate 1 and sacrificing layer 2. The structure layer 3 is patterned in a shape in accordance with necessity, and in the structure layer 3 an etching opening 3a that reaches the sacrificing layer 2 is formed. Thereafter, as shown in FIG. 6B, through the etching opening 3a the sacrificing layer 2 is etched and removed. Thereby, a three-dimensional structure with a hollow portion a below the structure layer 3 can be obtained.

Still furthermore, in the case of in the manufacture of a semiconductor device a lower electrode of a cylindrical capacitor being formed, firstly, as shown in FIG. 7A, above a substrate 1, a first sacrificing layer 2 is formed followed by disposing a hole pattern 2a thereto, and then with an inner wall of the hole pattern 2a covered a lower electrode layer 5 is deposited. Subsequently, so as to fill the inside of the hole pattern 2a, on a lower electrode layer 5, a second sacrificing layer 6 is further deposited followed by polishing and removing a top portion of the sacrificing layer 6 and the lower electrode layer 5 therebelow, and thereby the lower electrode layer 5 is formed in cylinder. Thereafter, as shown in FIG. 7B, the sacrificing layers 2 and 6 are selectively etched and removed, and thereby on the substrate 1 a cylindrical lower electrode 5a is formed as a three-dimensional structure.

In the case of in the abovementioned etching process a chemical liquid being used as an etchant, in the drying process thereof, in some cases, a structure (such as lower electrode) formed owing to the etching is destroyed owing to the surface tension of a rinse liquid. As an inhibitive method thereof, a method in which after a rinse liquid is replaced with a super critical fluid that combines the diffusivity of a gas and the solubility of a liquid, the super critical fluid is vaporized is proposed. In particular, in the case of the rinse liquid being impregnated in the pattern, when after the rinse liquid is replaced with liquid carbon dioxide, a substrate on which the pattern is formed is heated and thereby the pattern is heated to a temperature higher than a temperature of the inside of a vessel where liquid carbon dioxide is filled and, the rinse liquid remaining in the pattern can be rapidly released outside. See, generally, Japanese Patent Document No. 2002-313773.

Furthermore, a process is also proposed in which when a processing fluid in which an etching reaction species is contained in a super critical fluid is used to etch such that a drying process can be effectively eliminated.

However, such etching processes have problems as detailed below. For instance, in the formation of the three-dimensional structure that has a hollow portion as explained with FIGS. 6A and 6B, as the hollow portion a that is formed according to the etching becomes larger relative to the etching opening 3a, it becomes difficult to remove the sacrificing layer 2 by means of the etching. Furthermore, in the three-dimensional structure (lower electrode of the cylindrical capacitor) explained with FIGS. 7A and 7B, as an aspect ratio of a cylindrical shape becomes larger, it becomes difficult to etch and remove the sacrificing layers 2 and 6.

This is due to an etching mechanism that is described below. That is, with the progress of the etching of the sacrificing layers 2 and 6, an etching reaction species contained in the etchant is consumed. Accordingly, in order to further forward the etching, it is necessary to remove the etchant that contains a deactivated etching reaction species from the etching opening and to supply a new etchant from the etching opening. However, with the progress of the etching, the hollow portion a becomes larger and the aspect ratio of the cylindrical shape becomes higher; accordingly, it becomes difficult to exchange the etchant through the fine etching opening and a replacement efficiency of the etchant to an etched portion becomes low. As a result, with the progress of the etching, the etching rate of the sacrificing layers 2 and 6 is remarkably lowered and it becomes difficult to etch and remove the sacrificing layers 2 and 6.

As mentioned above, in the case of the sacrificing layers 2 and 6 becoming difficult to be completely etched and removed and thereby residue of the sacrificing layers 2 and 6 being generated, the shape accuracy of the etching, that is, the shape accuracy of the three-dimensional structure is deteriorated. Thereby, the operating characteristics of a micromachine or a semiconductor device having the three-dimensional structure are deteriorated.

Furthermore, owing to the abovementioned deterioration of the etching rate, an etching time is elongated as a whole. Accordingly, even on a surface of the structure layer, an influence of the etching is exerted, and thereby, in some cases, the characteristics of the micromachine provided with the three-dimensional structure are deteriorated. For instance, in a light modulation micromachine, a surface of the structure layer is constituted of a light-reflective layer such as an aluminum film. In this case, when a surface of the aluminum film is affected by the etching, original reflective characteristics become difficult to obtain.

### SUMMARY OF THE INVENTION

The present invention relates to an etching process. In particular, the present invention relates to an etching process that is applied when in the manufacture of a semiconductor device or a micromachine, a sacrificing layer is selectively etched and removed to form a fine three-dimensional structure.

In an embodiment an etching process is provided that allows etching and removing a sacrificing layer with a sufficient rate from a fine etching opening and thereby can form a structure that has a large hollow portion or a space having a complicated configuration and a structure high in the aspect ratio with excellent shape accuracy and without deteriorating a surface state.

In an etching process in an embodiment for achieving such an object, with a work exposed to a processing fluid that contains an etching reaction species, light is intermittently illuminated on a surface of the work to heat. Thereby, the processing fluid in the neighborhood of the work is intermittently heated and thereby expanded or contracted. At this time, the processing fluid is maintained in a state where it flows relative to the work.

In such an etching process, a surface of the work is intermittently illuminated with light, and thereby the processing fluid in the neighborhood of the work is indirectly heated owing to the thermal conduction from the work. Thereby, the processing fluid is efficiently heated from a side in contact with the work and expands. Owing to the expansion, the density of the processing fluid in the neighborhood of the work is lowered. Accordingly, even when the work has a hollow portion on a surface side thereof, or even when the work has a hole or a groove, the processing fluid in the hollow portion, hole or groove is also heated from a surface of the work in contact with the processing fluid and expanded and thereby exhausted from the hollow portion, hole or groove. Furthermore, since the heating is intermittently applied, between the heating and the heating, the heat of the work is dissipated to the work itself and to the processing fluid that flows relative to the work. Following the heat dissipation, the processing fluid in the hollow portion, hole or groove is cooled and contracted, a processing fluid that is flowingly supplied to a surface of the work and contains a new etching reaction species is forcibly introduced into the hollow portion, hole or groove to replace the processing fluid. Accordingly, owing to the intermittent heating due to the light illumination, the abovementioned forcible replacement of the processing fluid is repeatedly and efficiently carried out. As a result, the etching rate in the hollow portion, hole or groove can be maintained.

Thereby, according to the etching process in an embodiment, the etching can be performed without leaving a sacrificing layer in a hollow portion that has a complicated shape or is large to an etching opening and furthermore in a hole or groove having a high aspect ratio. Accordingly, an improvement in the precision in the etching shape can be attained and since the etching time can be shortened, the surface nature can be inhibited from deteriorating owing to the etching. As a result, for instance, a micromachine or a semiconductor device provided with a three-dimensional structure portion can be improved in the operating characteristics.

Additional features and advantages of the present invention are described in, and will be apparent from, the following Detailed Description of the Invention and the figures.

### BRIEF DESCRIPTION OF THE FIGURES

FIG. 1 is a configuration diagram of a processor that is used in an etching process according to an embodiment.

FIG. 2 is a flowchart showing an etching process according to an embodiment.

FIG. 3 is a graph showing intermittent illumination of illumination light in an etching process according to an embodiment.

FIGS. 4A and 4B are diagrams for explaining effects of an etching process according to an embodiment.

FIG. 5 is a graph showing effects of an etching process according to an embodiment.

FIGS. 6A and 6B are sectional views for explaining an example of an existing etching process.

FIGS. 7A and 7B are sectional views for explaining another example of an existing etching process.

### DETAILED DESCRIPTION OF THE INVENTION

The present invention relates to an etching process. In particular, the present invention relates to an etching process that is applied when in the manufacture of a semiconductor device or a micromachine, a sacrificing layer is selectively etched and removed to form a fine three-dimensional structure.

Various embodiments of an etching process according to the present invention will be explained in greater detail below. An example of a configuration of a processor that is preferably used in the etching device will be explained.

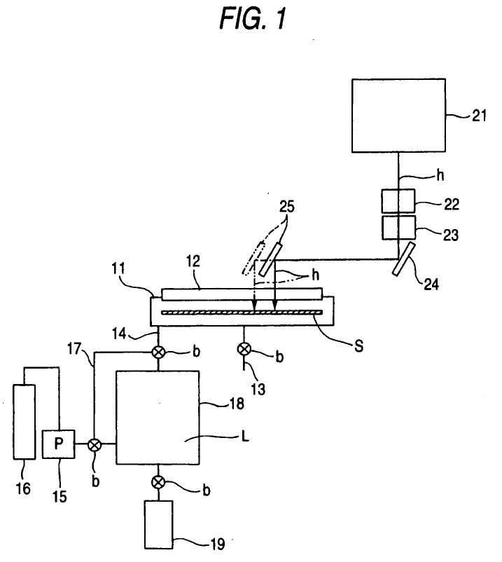

FIG. 1 is a schematic configuration diagram showing an example of a processor that is used in an etching process according to an embodiment. The processor has a processing chamber 11 where the etching is carried out. In the processing chamber 11, a substrate S that is a work can be housed and a temperature inside thereof can be maintained at a predetermined value. Furthermore, at a position that faces a surface (surface that is to be etched) of the substrate S that is housed in the processing chamber 11, an optical window 12 that transmits illumination light (such as laser light or lamp light) h illuminated on the substrate S is disposed. For the optical window 12, known synthesized quartz or fluorite can be preferably used.

Furthermore, to the processing chamber 11, via a valve b, an exhaust tube 13 and a fluid supply tube 14 are connected and thereby the inside of the processing chamber 11 is constituted so as to be maintained at a predetermined pressure atmosphere. Among these, to the fluid supply tube 14, via a pump 15, a carbon dioxide (CO₂) tank 16 is connected to supply CO₂ to the inside of the processing chamber 11 under a predetermined pressure. Furthermore, in parallel with a connection tube 17 between the pump 15 and the fluid supply tube 14, via the valve b, a mixing tank 18 is connected. To the mixing tank 18, via the valve b, a supply source 19 for supplying an entrainer such as an etching reaction species (such as hydrofluoric acid vapor and water vapor) or a solubility agent is connected and in the mixing tank 18 a processing fluid L in which the entrainer is dispersed (dissolved) in CO₂ at a predetermined concentration is reserved under a predetermined temperature and pressure.

Still furthermore, to the processor, a light source 21 that oscillates illumination light h in pulse is disposed. On a light path of the illumination light h that is illuminated from the light source 21, in turn from a side of the light source 21, an attenuator 22, a collimator 23 and two freely movable mirrors 24 and 25 are disposed. Owing to the two mirrors 24 and 25, the illumination light h oscillated in pulse from the light source 21 transmits the optical window 12 and is illuminated on a surface of the substrate S housed in the processing chamber 11, and furthermore owing to the drive of the two mirrors 24 and 25 the illumination light h is scanned over an entire region of the surface of the substrate S. Furthermore, the energy density of the illumination light h illuminated on the substrate S is controlled to a predetermined value by use of the attenuator 22 and the collimator 23.

According to such a processor, CO₂ that does not contain an impurity such as an entrainer, or a processing fluid L that is maintained at a predetermined temperature and pressure with the entrainer such as hydrofluoric acid vapor or water vapor dispersed in CO₂ at a predetermined concentration can be supplied into the processing chamber 11 maintained at a predetermined temperature and a predetermined pressure. Accordingly, in the processing chamber 11, CO₂ can also maintain a super critical state. Furthermore, to the substrate S that is exposed to a predetermined atmosphere in the processing chamber 11, the illumination light h oscillated in pulse can be illuminated at a predetermined energy density.

A configuration of the abovementioned processor is one example of a number of different and suitable examples, in accordance with a substance that is used as a processing fluid L. The CO₂ tank 16 is changed to another gas tank and an entrainer that is supplied from the supply source 19 can be properly selected.

Furthermore, when the illumination light h oscillated in pulse from the light source 21 can be scanned to an entire surface of the substrate S, in place of the mirrors 24 and 25, an optical fiber may be used. Still furthermore, as the light source 21 that oscillates the illumination light h in pulse, one in which a laser light source or a lamp that emits light having a wavelength in a UV region is oscillated in pulse can be used. However, in the processor that is used in the etching process in an embodiment, as far as the illumination light h can be intermittently illuminated on the substrate S housed in the processing chamber 11, it is not restricted to the use of the light source 21 that oscillates the illumination light h in pulse. For instance, even when a light source 21 that continuously emits light like a dielectric barrier discharge lamp is used, when between the light source 21 and the optical window 12 a shield plate that can be freely opened and closed with a predetermined period is disposed, the illumination light h can be intermittently illuminated onto the substrate S. Accordingly, a processor with such a configuration also can be used.

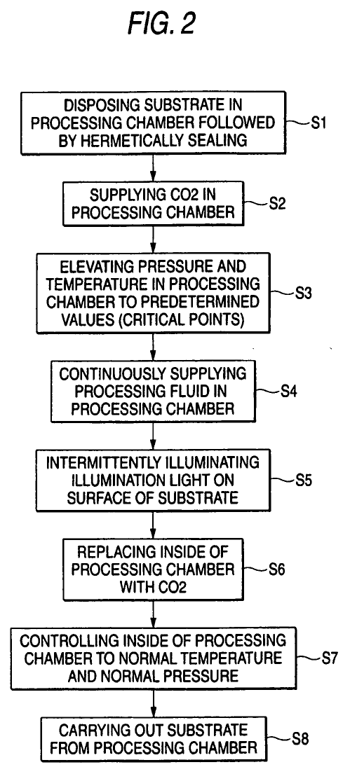

An embodiment of an etching process that uses a processor will be explained based on a flowchart shown in FIG. 2 with reference to FIG. 1. Here, assuming a case where in a front surface side of the substrate S, from a fine etching opening, a sacrificing layer is selectively etched and removed, an embodiment of an etching process will be explained.

Firstly, in a first step S1, a substrate S that is a work is housed and disposed in a processing chamber 11 and a carry-in port of the substrate S is closed to hermetically seal the inside of the processing chamber 11.

Subsequently, in a second step S2, from a fluid supply tube 14 into the processing chamber 11, pure CO₂ that does not contain an entrainer or other substance is supplied. Here, simultaneously the processing chamber 11 is evacuated. Thus, until the inside of the processing chamber 11 is completely replaced with CO₂, the evacuation of the inside of the processing chamber 11 and the supply of CO₂ are continued.

Thereafter, in a third step S3, with the evacuation of the inside of the processing chamber 11 stopped, the supply of CO₂ into the processing chamber 11 is continued and a temperature inside of the processing chamber 11 is controlled, and thereby the pressure inside of the processing chamber 11 is made the critical pressure of CO₂ or more and a temperature is made the critical temperature or more. Thereby, the processing chamber 11 is filled with a super critical fluid of CO₂.

In the next place, in a fourth step S4, a processing fluid L in which an etching reaction species is dispersed (or dissolved) in CO₂ is continuously supplied into the processing chamber 11. At this time, the processing fluid L preheated and pre-pressurized in the mixing tank 18 is supplied from the fluid supply tube 14 into the processing chamber 11. Furthermore, the inside of the processing chamber 11 is properly evacuated, and thereby the pressure and temperature inside of the processing chamber 11 are allowed to maintain a state of the third step S3. In the processing fluid L, as needs arise the etching reaction species may be dissolved blended with a solubility agent. Still furthermore, in the processing fluid L, as an entrainer other than the etching reaction species and the solubility agent, in super critical fluid CO₂ cleaning, known chemicals such as methanol, hexane, octane or a mixture thereof may be added.

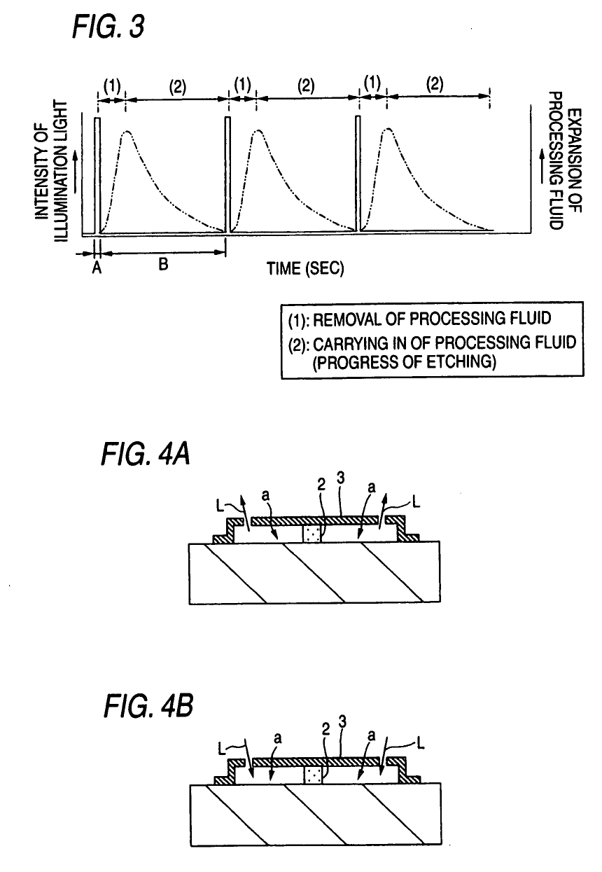

Subsequently, in a fifth step S5, like in the fourth step S4, with the processing fluid L continuing to supply into the processing chamber 11, illumination light h oscillated in pulse from the light source 21 is illuminated through the optical window 12 onto the substrate S in the processing chamber 11. At this time, as shown with a solid line in FIG. 3, to the respective portions of the substrate S, illumination light h with a predetermined wavelength is illuminated repeatedly with a predetermined illumination time A and a predetermined oscillation period B.

Here, a wavelength and an illumination time A of the illumination light h are determined with an intention of heating only an outer-most surface of the substrate S with the thermal damage of the substrate S inhibiting. Specifically, in order that a heating region due to the illumination light h may be confined in a range shallower than a depth up to 100 nm from a surface of the substrate S, it is preferable that a wavelength of the illumination light h is set in a UV region and the illumination time A of the illumination light h is set at 100 nsec or less. For instance, in the case of the substrate S being made of a silicon substrate, a third harmonics (wavelength: 355 nm) of Nd: YAG laser light is preferably used as the illumination light h, thereby an absorption depth of the illumination light h is confined within substantially 10 nm, that is, the heating range of the substrate S is confined only to a very surface.

Furthermore, an oscillation period B of the illumination light h is set at a time necessary for a surface temperature of a substrate S heated owing to the illumination light h to decrease to an extent that balances with an internal temperature of the substrate S or more, for instance, at 0.1 second and or more.

The intermittent illumination of the illumination light h to the respective portions of the substrate S as mentioned above is repeated the predetermined number of periods until a sacrificing layer that is to be removed by the etching is completely removed, and the number is previously determined according to an experiment. Furthermore, in order that the intermittent illumination of the illumination light h to the respective portions of the substrate S may be carried out over an entire region of a surface of the substrate S, the mirrors 24 and 25 are driven so as to scan an illumination position. At this time, in order that the illumination light h may be illuminated with a uniform energy density over an entire region of the surface of the substrate S, the illumination light h is scanned.

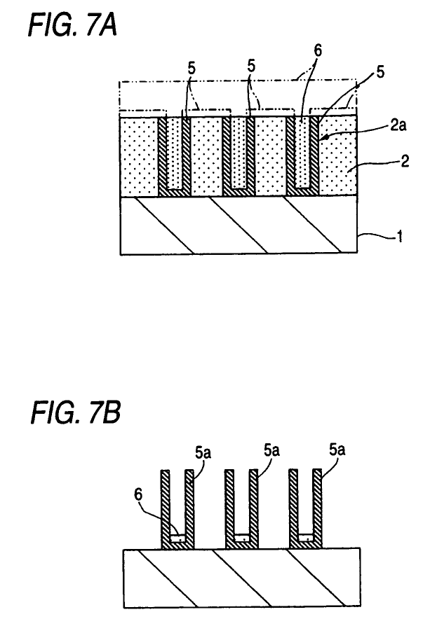

In the case of sacrificing layers inside and outside of a hole pattern or a groove pattern with a high aspect ratio such as a lower electrode layer 5 explained with FIG. 7 being etched, in order that the illumination light h may be illuminated on a sidewall of a hole pattern or groove pattern gradually exposed owing to the etching, an angle of illumination of the illumination light h is preferably controlled.

After, as mentioned above, the illumination light h is intermittently illuminated on the substrate S, in a sixth step S6, pure CO₂ in which an etching reaction species is not blended is introduced from the fluid supply tube 14 into the processing chamber 11 and thereby the inside of the processing chamber 11 is replaced with CO₂. At this time, the inside of the processing chamber 11 is maintained at a predetermined temperature and pressure where CO₂ is maintained in a super critical state.

Thereafter, in a seventh step S7 the inside of the processing chamber 11 is evacuated to depressurize it to substantially atmospheric pressure. At this time, in order to inhibit the structure formed in the etching step of the fifth step S5 from being destroyed, it is important that the inside of the processing chamber 11 is depressurized with a temperature thereof being controlled and thereby CO₂ inside of the processing chamber 11 is transferred directly from the super critical state to a gaseous state. Subsequently, after the inside of the processing chamber 11 is depressurized to substantially atmospheric pressure, a temperature inside of the processing chamber 11 is lowered to substantially room temperature.

After the above, in an eighth step S8, the substrate S is carried out of the processing chamber 11, and thereby a sequence of the etching steps comes to completion.

According to the above-explained etching process, in the fifth step S5, the illumination light h is intermittently illuminated on a surface of the substrate S, and thereby a surface layer of the substrate S is intermittently heated. Thereby, the processing fluid L in the neighborhood of the surface of the substrate S is indirectly heated owing to the thermal conduction from the surface layer of the heated substrate S. Thereby, as shown in a portion (1) of a chain double-dashed line of FIG. 3, the processing fluid L is efficiently heated from a side that is in contact with the substrate S to expand. Such a volume expansion of the processing fluid L, being indirect one owing to the heat dissipation from the substrate S heated by illuminating light, occurs belatedly from the illumination time A of the illumination light h. Then, owing to such volume expansion of the processing liquid L, as shown in FIG. 4A, even in the case of the substrate S having a hollow portion a on a surface side thereof, as shown with an arrow mark in the drawing, the processing fluid L in the hollow portion a expands and is forcibly removed from the inside of the hollow portion a. In this case, when a surface of the structure 3 is heated owing to the intermittent illumination of illumination light h, the heat propagates speedily through the structure and heats the processing fluid L on a side of the hollow portion a.

Thereby, the processing fluid L containing the etching reaction species that is deactivated owing to the etching and a reaction product is excluded from the hollow portion a. Furthermore, into the processing chamber 11, the processing fluid L is flowingly supplied; accordingly, the processing fluid L excluded from the inside of the hollow portion a is exhausted from the inside of the processing chamber 11 as the processing fluid L flows.

Now, since the surface layer of the substrate S is thus intermittently heated, between the heating and the heating, the heat of the substrate S is dissipated to the substrate S itself and to the processing fluid L and thereby the substrate S is cooled. Thereby, as shown in a portion (2) of a chain double-dashed line graph of FIG. 3, the processing fluid L begins to be cooled and to contract. Then, as shown in FIG. 4B, into the hollow portion a, the processing fluid L is forcibly flowed. In this case, the processing fluid L is flowingly supplied into the processing chamber 11. Accordingly, a processing fluid L containing a new etching reaction species is flowed into the hollow portion a. Thereby, the processing fluid L in the hollow portion a is replaced, and owing to the processing fluid L that has newly flowed in the sacrificing layer 2 is further etched. Such a replacement of the processing fluid L, without restricting to the hollow portion a, even in the case of a sacrificing layer in a fine hole pattern or a groove pattern being etched, can be similarly performed.

Accordingly, owing to the abovementioned intermittent heating, the abovementioned forcible replacement of the processing fluid is repeatedly carried out. As a result, the etching rate can be maintained inside of the hollow portion a (hole and groove).

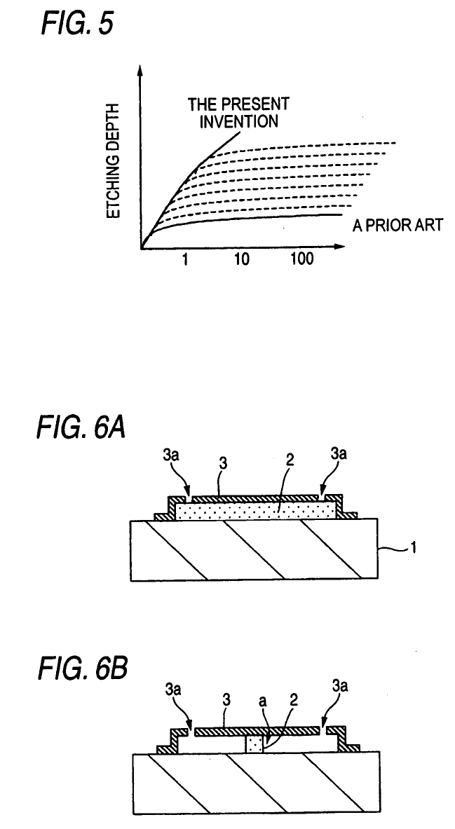

As shown in a graph of FIG. 5, different from etching depths (solid line) in an existing etching process, as shown with dotted lines in the drawing, as the number of times of repetition of light illumination increases, the etching depths can be deepened, and thereby by repeating the predetermined number of times a necessary etching depth can be obtained. The etching depth here is a distance from an etching opening.

Furthermore, since the etching rate can be secured, an etching time can be shortened as a whole. Thereby, an outer surface of the work and a portion that appears on a surface at an early stage of the etching can be shortened in an exposure time to the processing fluid, resulting in reducing adverse affect such as corrosion and the etching.

From the above, according to the etching process in an embodiment, owing to the etching through a fine etching opening, a hollow portion that is complicatedly shaped or a hollow portion that is large relative to an etching opening, furthermore the inside of a hole and groove with a high aspect ratio can be formed without remaining the etching residue, with excellent shape accuracy and without deteriorating a surface state. As a result, for instance, the operating characteristics of a micromachine and a semiconductor device provided with a three-dimensional structure portion can be improved.

An etching process in an embodiment will be explained below. The etching process is a process in which only on a portion of a substrate S selected through a mask pattern illumination light h is illuminated and a sequence of steps is similar to that explained above with respect to a flowchart of FIG. 2.

In this case, in the processor explained with FIG. 1, with a mask in which a pattern that restricts an illumination range of the illumination light h is formed disposed on an optical path of illumination light h between the light source 21 and the substrate S, the fifth step S5 is carried out.

Thereby, in a region of one shot during which the illumination light h is illuminated, intensity distribution of the illumination light h can be formed. Accordingly, for instance, in the case of, such as shown in FIGS. 4A and 4B, a hollow portion a being formed below a structure layer 3 owing to the etching of the sacrificing layer 2, when to a complicated structure layer 3 the illumination light h is not illuminated in the neighborhood of the etching opening 3a and illuminated only on a position remote from the etching opening 3a of the hollow portion a, inside of the already formed hollow portion a the convection of a processing fluid L can be locally generated. Accordingly, replacement efficiency of the processing fluid L in an already formed hollow portion a can be further improved.

As previously discussed, an example in which a processing fluid L in which an etching reaction species is contained in a super critical fluid (CO₂ super critical fluid) is used to etch is shown. However, the etching process in an embodiment, without restricting to the etching process that uses the processing fluid having such a form, may be any suitable etching process that uses a gaseous or liquid processing fluid. Furthermore, in the case of the etching reaction species itself being fluid, other super critical fluid or gas, and furthermore a carrier fluid such as a liquid, can be used as needs arise.

It should be understood that various changes and modifications to the presently preferred embodiments described herein will be apparent to those skilled in the art. Such changes and modifications can be made without departing from the spirit and scope of the present invention and without diminishing its intended advantages. It is therefore intended that such changes and modifications be covered by the appended claims.

1. An etching process comprising:
illuminating light intermittently on a work surface to heat while the work surface is exposed to a processing fluid that contains an etching reaction species thereby intermittently heating the processing fluid in proximity of the work surface to expand or contract; and
at the same time, maintaining the processing fluid in a state where it flows relative to the work surface.

2. The etching process according to claim 1, wherein the etching reaction species includes a substance in a super critical state.

3. The etching process according to claim 1, wherein the illumination light is illuminated on a selected position on the work surface through a mask pattern.

4. The etching process according to claim 1, wherein the illuminating light is carried out by pulse oscillation due to any one of lamp light and laser light.

5. The etching process according to claim 4, wherein the illuminating light is carried out by pulse oscillation at an illuminating time of about 100 nsec or less.

6. The etching process according to claim 1, wherein light illuminated on the work surface is UV light.
